(19) United States
(12) Patent Application Publication
(10) Pub. No.: US 2016/0005796 A1
(43) Pub. Date: Jan. 7, 2016

(54) ILLUMINATING DEVICE AND MANUFACTURING METHOD THEREOF

(71) Applicant: BOE TECHNOLOGY GROUP CO., LTD., Beijing (CN)

(72) Inventor: Li SUN, Beijing (CN)

(73) Assignee: BOE TECHNOLOGY GROUP CO., LTD., Beijing (CN)

(21) Appl. No.: 14/416,348

(22) PCT Filed: May 24, 2014
(86) PCT No.: PCT/CN2014/078355

§ 371 Date: Jan. 22, 2015

(30) Foreign Application Priority Data
Oct. 18, 2013 (CN) 201310492795.8

(51) Int. Cl. H01L 27/32; H01L 51/56; H01L 51/52

(52) U.S. Cl. CPC H01L 27/322; H01L 51/5253; H01L 51/56; H01L 2251/303; H01L 2251/558; H01L 2251/5361

(57) ABSTRACT

An illuminating device is provided, which includes: a substrate (110, 210), and a light source (120, 220) and a light-emitting layer (131, 132, 133, 231, 232, 233) which are disposed on the substrate (110, 210). A wavelength of light emitted by the light source (120, 220) is smaller than a wavelength of light emitted after the light-emitting layer (131, 132, 133, 231, 232, 233) is excited, the light emitted by the light source (120, 220) is adapted for exciting the light-emitting layer (131, 132, 133, 231, 232, 233) to emit light, and the light-emitting layer (131, 132, 133, 231, 232, 233) is made from a long-persistence material. The illuminating device achieves emergency lighting in the case of no power supply.

### TECHNICAL FIELD

Embodiments of the present disclosure relate to an illuminating device and a manufacturing method thereof.

### BACKGROUND

An organic light-emitting diode (OLED) can be easily disposed on a planar substrate or a flexible substrate to form a planar or curved-surface light source, has the advantages such as low energy consumption and the like, and can replace the technologies of forming a surface light source by using point light sources or line light sources and a light guide plate and a diffusion film.

The method for forming a white surface light source includes the step of obtaining white light by mixing red, green and blue (RGB) light or mixing yellow and blue (YB) light. In order to produce RGB or YB light, OLED units for emitting light of these colors may be adopted and the light emitted by the OLED units is mixed to produce white light. OLED units for emitting short-wavelength light may also be adopted; the short-wavelength light emitted excites a light-emitting layer to emit long-wavelength light; and further, the long-wavelength light is mixed to form white light. For instance, blue light emitted by a blue OLED excites a red light-emitting layer and a green light-emitting layer to respectively produce red light and green light, and further, the red light and the green light are mixed with the blue light to produce white light; or the blue light emitted by the blue OLED excites a yellow light-emitting layer to produce yellow light, and further, the yellow light is mixed with the blue light to produce white light. The working principle of the above-mentioned excitation is as follows: high-energy and short-wavelength light excites light of lower energy and longer wavelength, and photons are adopted to produce photons.

But the above-mentioned OLED light source cannot emit light continuously in the case of power failure, and hence emergency lighting cannot be achieved.

### SUMMARY

At least one embodiment of the present disclosure provides an illuminating device and a manufacturing method thereof, which can achieve emergency lighting in the case of no power supply.

At least one embodiment of the present disclosure provides an illuminating device, which comprises: a substrate, and a light source and a light-emitting layer which are disposed on the substrate. A wavelength of light emitted by the light source is smaller than a wavelength of light emitted by the light-emitting layer after the light-emitting layer is excited. The light emitted by the light source is adapted for exciting the light-emitting layer to emit light. The light-emitting layer comprises a long-persistence material.

In one embodiment, the light source is disposed on the substrate; the light-emitting layer is disposed on the light source; and a light-emitting surface of the light source faces the light-emitting layer.

In one embodiment, the illuminating device further comprises a transparent sealing layer disposed on the light-emitting layer.

In one embodiment, the light-emitting layer is disposed on the substrate which is a transparent substrate; the light source is disposed on the light-emitting layer; and a light-emitting surface of the light source faces the light-emitting layer.

In one embodiment, the illuminating device further comprises a sealing layer disposed on the light-emitting layer.

At least one embodiment of the present disclosure further provides a method for manufacturing an illuminating device. The method comprises forming a light source and a light-emitting layer on a substrate. A wavelength of light emitted by the light source is smaller than a wavelength of light emitted by the light-emitting layer after the light-emitting layer is excited. The light emitted by the light source is adapted for exciting the light-emitting layer to emit light. The light-emitting layer comprises a long-persistence material.

In one embodiment, the light source is formed on the substrate, and a light-emitting surface of the light source is away from the substrate; and the light-emitting layer is formed on the light-emitting surface of the light source.

In one embodiment, the method further comprises forming a transparent sealing layer on the light-emitting layer after forming the light-emitting layer.

In one embodiment, the method comprises: forming the light-emitting layer on the substrate which is a transparent substrate; and forming the light source on the light-emitting layer, and the light-emitting surface of the light source faces the light-emitting layer.

In one embodiment, the method further comprises forming a sealing layer on the light source after forming the light source on the light-emitting layer.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and thus are not limitative of the disclosure.

FIG. 1 is a schematic structural view of an illuminating device provided by an embodiment of the present disclosure;

FIG. 2 is a schematic structural view of an illuminating device provided by an embodiment of the present disclosure;

FIG. 3 a schematic structural view of an illuminating device provided by another embodiment of the present disclosure; and

FIG. 4 is a schematic structural view of an illuminating device provided by still another embodiment of the present disclosure.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

The illuminating device provided by at least one embodiment of the present disclosure includes: a substrate, and a light source and a long-persistence light-emitting layer which are disposed on the substrate. The wavelength of light emitted by the light source is smaller than the wavelength of light emitted by the light-emitting layer after the light-emitting layer is excited, and the light emitted by the light source is adapted for exciting the light-emitting layer to emit light. Because the light-emitting layer is made from a long-persistence material, emergency lighting can also be achieved in the case of no power supply. Further detailed description will be given below to the specific implementation modalities of the present disclosure with reference to the accompanying drawings and the embodiments. The following embodiments are only intended to illustrate the present disclosure and not intended to limit the scope of the present disclosure.

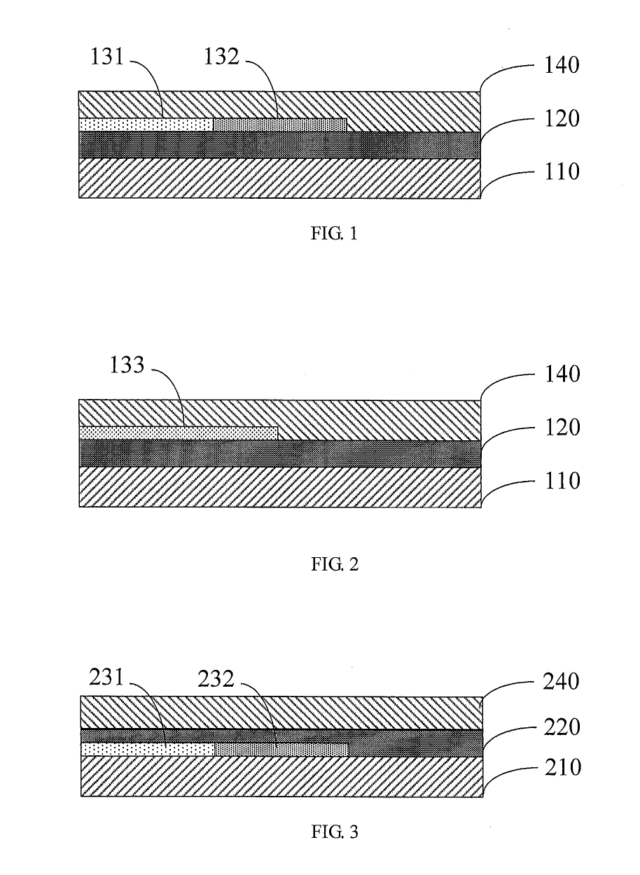

FIG. 1 is a schematic structural view of an illuminating device provided by at least one embodiment of the present disclosure. Taking a top-emission white-light illuminating device as an example, a blue light source (may be a blue-light OLED, and the wavelength of blue light is smaller than 450 nm) may be adopted to excite a green light-emitting layer and a red light-emitting layer to respectively emit green light (with the wavelength ranging from 530 nm to 580 nm) and red light (with the wavelength ranging from 600 nm to 650 nm), and further, the excited green light and red light are mixed with the blue light emitted by the blue light source to produce white light. As illustrated in FIG. 1, the illuminating device includes a substrate 110, a blue light source 120 disposed on the substrate 110 and a light-emitting layer disposed on the blue light source 120. The light-emitting layer includes a green light-emitting layer 131 and a red light-emitting layer 132. In order to obtain the red light and the green light through excitation, a light-emitting surface (light-output surface) of the blue light source 120 faces the green light-emitting layer 131 and the red light-emitting layer 132. In order to obtain the white light through mixture, the green light-emitting layer 131 and the red light-emitting layer 132 do not completely cover the light-emitting surface of the blue light source 120. If the white light is not required to be emitted, the green light-emitting layer 131 and the red light-emitting layer 132 are only excited to emit light and may also completely cover the light-emitting surface of the blue light source 120.

In order to realized that the green light-emitting layer 131 and the red light-emitting layer 132 are protected and can give out light, a transparent sealing layer 140 disposed on the green light-emitting layer 131 and the red light-emitting layer 132 is further included. The transparent sealing layer 140 can achieve light transmission. In one embodiment, the transparent sealing layer 140 may also be provided with a plurality of structures for the uniform mixture of light. The structures for the uniform mixture of light may be similar to light mixing structures in a light guide plate of a backlight of a liquid crystal display device. In at least one embodiment of the present disclosure, a light mixing layer may also be separately formed on one side of the transparent sealing layer 140, facing or being away from the light-emitting layer.

FIG. 2 is a schematic structural view of an illuminating device provided by at least one embodiment of the present disclosure. As illustrated in FIG. 2, in order to emit white light, in the light-emitting layer, the green light-emitting layer 131 and the red light-emitting layer 132 may be replaced by a yellow light-emitting layer 133.

In at least one embodiment of the present disclosure, in order to continuously provide a light source after a power failure, the light-emitting layer is made from a long-persistence material. which, for instance, may include silicate, aluminate or carbonate which are each doped with rare earth (for example, Eu, Sin or Ce, etc.) ions, or include silicate, aluminate or carbonate which are each doped with transition metal (Cu or Mn, etc.) ions, or any combination thereof.

In at least one embodiment of the present disclosure, if the light-emitting layer is too thin, the excited red light and green light (or yellow light) is inadequate and too weak; and if the light-emitting layer are too thick, the transmission path of the red light and the green light (or the yellow light) is too long, and finally the transmitted light is also weak. For instance, the thickness of the light-emitting layer may be from 0.5 μm to 100 μm.

In the above-mentioned long-persistence material, because shallow electron traps lower than conduction bands are formed in energy gaps of rare earth or this material, light of blue wave band can excite electrons to the conduction bands; then the electrons relax to trap levels and subsequently relax to valence bands from the trap levels; and hence long-wavelength light with energy lower than that of light of the excitation wavelength is emitted. By selecting doped ions with different energy levels and a matrix with band gaps, red, green or yellow light emitted due to excitation can be produced. As for shallow electron traps formed by the genergy levels of doped ions, electrons relaxing to the trap levels after excitation need a certain excitation energy to escape from the traps and to relax to the ground state with lower energy, and, in the case of no other excitation energy, can jump to the ground state with a certain probability by thermal vibration. Therefore, the process of light emission continues for a period of time. The light emission for the period of time is produced without external photoelectric excitation, which is usually called persistence. A long-persistence material has high trap concentration and appropriate trap depth, so that electrons captured by the electron traps after excitation escape from the traps with a certain probability for deexcitation and emission, and hence the light emission due to persistence can continue for several hours.

At least one embodiment of the present disclosure provides a method for manufacturing an illuminating device, and the method includes: forming a light source and a corresponding light-emitting layer on a substrate. and making the wavelength of light emitted by the light source smaller than the wavelength of light emitted by the light-emitting layer after the light-emitting layer is excited, and the light emitted by the light source adapted for exciting the light-emitting layer to emit light.

With regard to forming the light source on the substrate, because the illuminating device provided by the embodiment adopts top emission, a light-emitting surface of the light source is away from the substrate. The light source may be a blue OLED light source. The blue OLED may adopt fluorescent or phosphorescent emission, and may have a common structure with a single light-emitting layer, a structure with a plurality of light-emitting layers, or a stacked structure formed by the series connection of a plurality of units. A material of the organic layer in the light source may be made from small molecules, or a polymer. The method for manufacturing the OLED structure, for instance, is vacuum thermal evaporation, inkjet printing, spin-coating or a combination of the above-mentioned means. Electrodes of the OLED structure may be made from one of the metals such as Ag, Mg and Al or an alloy thereof, and may also be made from conductive metal oxide such as indium tin oxide and zinc tin oxide.

The long-persistence light-emitting layer is formed on the light-emitting surface of the light source. If the white light is emitted by mixing light, the light-emitting layer does not completely cover the light-emitting surface of the light source. For instance, the light-emitting layer is formed by spin-coating, inkjet printing or screen printing in a corresponding area of the light-emitting surface of the light source.

The method further includes the step of forming a transparent sealing layer on the light-emitting layer after the step of forming the light-emitting layer.

The illuminating device provided by some embodiments of the present disclosure can emit light continuously for a period of time in the case of no power supply, and hence achieve emergency lighting in the case of power failure.

At least one embodiment of the present disclosure further provides a structure of a bottom-emission illuminating device. Similarly, the case of emitting white light is taken as an example. As illustrated in FIG. 3, the illuminating device includes a substrate 210, a light-emitting layer disposed on the substrate 210 and a blue light source 220 disposed on the light-emitting layer. The light-emitting layer includes a green light-emitting layer 231 and a red light-emitting layer 232. In order to obtain red light and green light through excitation and to obtain white light by mixing the light, a light-emitting surface of the blue light source 220 faces the green light-emitting layer 231 and the red light-emitting layer 232, and the green light-emitting layer 231 and the red light-emitting layer 232 do not completely cover the light-emitting surface of the blue light source 220. If the white light is not required to be emitted, the green light-emitting layer 231 and the red light-emitting layer 232 are only excited to emit light and may also completely cover the light-emitting surface of the blue light source 220. Because the light-emitting layer is disposed between the substrate and the light source, namely the illuminating device adopts bottom emission, the substrate 210 is a transparent substrate which can achieve light transmission. In at least one embodiment of the present disclosure, the transparent substrate may also be provided with a plurality of structures for the uniform mixture of light. The structure for the uniform mixture of light may be similar to a light mixing structure in a light guide plate of a backlight of a liquid crystal display device. In at least one embodiment of the present disclosure, a light mixing layer may also be separately formed on one side of the transparent substrate, facing or being away from the light-emitting layer.

In order to protect the blue light source 220, a sealing layer 240 may also be formed on the blue light source 220.

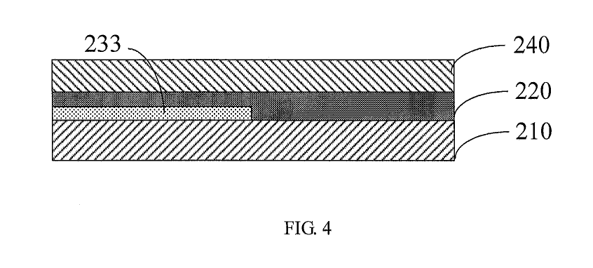

FIG. 4 is a schematic structural view of an illuminating device provided by at least one further embodiment of the present disclosure. As illustrated in FIG. 4, in order to emit white light, and the light-emitting layer, in the light-emitting layer, the green light-emitting layer 231 and the red light-emitting layer 232 are replaced by a yellow light-emitting layer 233.

In the embodiment, in order to continuously provide a light source after power failure, the light-emitting layer is made from a long-persistence material which, for instance, may be silicate, aluminate or carbonate which are each doped with rare earth (for example, Eu, Sm or Ce, etc.) ions, or silicate, aluminate or carbonate which are each doped with transition metal (Cu or Mn, etc.) ions, or any combination thereof. The thickness of the light-emitting layer may be from 0.5 μm to 100 μm. The light-emitting principle of the embodiment is the same with that of the above-mentioned embodiments of the present disclosure. No further description will be given herein.

At least one further embodiment of the present disclosure provides a method for manufacturing an illuminating device, and the method includes: forming a light source and a corresponding light-emitting layer on a substrate, and making the wavelength of light emitted by the light source smaller than the wavelength of light emitted by the light-emitting layer after the light-emitting layer is excited, and the light emitted by the light source adapted for exciting the light-emitting layer to emit light.

The long-persistence light-emitting layer is formed on the transparent substrate. For instance, the light-emitting layer is formed by spin-coating, inkjet printing or screen printing in a corresponding area of the transparent substrate.

The light source is formed on the light-emitting layer, and a light-emitting surface of the light source faces the light-emitting layer. The light source may be a blue OLED light source. The blue OLED may adopt fluorescent or phosphorescent emission, and may have a common structure with a single light-emitting layer, a structure with a plurality of light-emitting layers structure, or a stacked structure formed by the series connection of a plurality of units. A material of the organic layer in the blue OLED may be made from small molecules or a polymer. The method for manufacturing the OLED structure, for instance, is vacuum thermal evaporation, inkjet printing, spin-coating or a combination of the above-mentioned means. Electrodes of the OLED structure may be made from one of the metals such as Ag, Mg and Al or an alloy thereof, and may also be made from conductive metal oxide such as indium tin oxide and zinc tin oxide.

The method further includes the step of forming a sealing layer on the light source after the step of forming the light source.

The illuminating device provided by some embodiments of the present disclosure utilizes the down-conversion characteristic of a long-persistence material (high-energy and short-wavelength light is adopted to produce light of lower energy and longer wavelength through excitation and photons are adopted to produce photons, which is referred to as down-conversion because the wavelength is longer), and adopt the light source for emitting short-wavelength light to emit light and to excite the long-persistence light-emitting layer for emitting long-wavelength light to emit light, so that the excited light-emitting layer can emit light continuously for a period of time in the case of no power supply, and hence emergence lighting in the case of power failure can be achieved.

The illuminating device provided by some embodiments of the present disclosure is, but not limited to, a white-light illuminating device. As long as the light source and the long-persistence light-emitting layer are changed, and light emitted by the light source and the long-persistence light-emitting layer are mixed to produce light of different colors or the light source excites the light-emitting layer to produce light of different colors, other embodiments can be obtained.

What are described above is related to the illustrative embodiments of the disclosure only and not limitative to the scope of the disclosure; the scopes of the disclosure are defined by the accompanying claims.

The application claims the benefit of Chinese Patent Application No. 201310492795.8, filed on Oct. 18, 2011 The disclosure content of the Chinese patent application is entirely incorporated herein by reference as part of the present application.

1. An illuminating device, comprising: a substrate, and a light source and a light-emitting layer which are disposed on the substrate, wherein
a wavelength of light emitted by the light source is smaller than a wavelength of light emitted by the light-emitting layer after the light-emitting layer is excited; the light emitted by the light source is adapted for exciting the light-emitting layer to emit light; and the light-emitting layer comprises a long-persistence material.

2. The illuminating device according to claim 1, wherein the light source is disposed on the substrate; the light-emitting layer is disposed on the light source; and a light-emitting surface of the light source faces the light-emitting layer.

3. The illuminating device according to claim 2, further comprising a transparent sealing layer disposed on the light-emitting layer.

4. The illuminating device according to claim 1, wherein the light-emitting layer is disposed on the substrate which is a transparent substrate; the light source is disposed on the light-emitting layer; and a light-emitting surface of the light source faces the light-emitting layer.

5. The illuminating device according to claim 4, further comprising a sealing layer disposed on the light-emitting layer.

6. The illuminating device according to claim 1, wherein the light-emitting layer comprises silicate, aluminate or carbonate which are each doped with rare-earth ions, or any combination thereof; or the light-emitting layer comprises silicate, aluminate or carbonate which are each doped with transition metal ions, or any combination thereof.

7. The illuminating device according to claim 1, wherein a thickness of the light-emitting layer is from 0.5 μm to 100 μm.

8. The illuminating device according to claim 1, wherein the light source comprises a blue organic light-emitting diode (OLED) light source, and the light-emitting layer comprises a red light-emitting layer and a green light-emitting layer.

9. The illuminating device according to claim 1, wherein the light source comprises a blue OLED light source, and the light-emitting layer comprises a yellow light-emitting layer.

10. A method for manufacturing an illuminating device, comprising:
forming a light source and a light-emitting layer on a substrate,
wherein a wavelength of light emitted by the light source is smaller than a wavelength of light emitted by the light-emitting layer after the light-emitting layer is excited; the light emitted by the light source is adapted for exciting the light-emitting layer to emit light; and the light-emitting layer comprises a long-persistence material.

11. The method for manufacturing the illuminating device according to claim 10, wherein
the light source is formed on the substrate, and a light-emitting surface of the light source is away from the substrate; and
the light-emitting layer is formed on the light-emitting surface of the light source.

12. The method for manufacturing the illuminating device according to claim 11, wherein the light-emitting layer is formed on the light-emitting surface of the light source by spin-coating, inkjet printing or screen printing.

13. The method for manufacturing the illuminating device according to claim 11, after forming the light-emitting layer, further comprising forming a transparent sealing layer on the light-emitting layer.

14. The method for manufacturing the illuminating device according to claim 10, wherein
the light-emitting layer is formed on the substrate, and the substrate is a transparent substrate; and
the light source is formed on the light-emitting layer, and a light-emitting surface of the light source faces the light-emitting layer.

15. The method for manufacturing the illuminating device according to claim 14, wherein the light-emitting layer is formed on the substrate by spin-coating, inkjet printing or screen printing.

16. The method for manufacturing the illuminating device according to claim 14, after forming the light source on the light-emitting layer, further comprising forming a sealing layer on the light source.

17. The method for manufacturing the illuminating device according to claim 10, wherein the light-emitting layer comprises silicate, aluminate or carbonate which are each doped with rare-earth ions, or any combination thereof; or the light-emitting layer comprises silicate, aluminate or carbonate which are each doped with transition metal ions, or any combination thereof.

18. The method for manufacturing the illuminating device according to claim 10, wherein a thickness of the light-emitting layer is from 0.5 μm to 100 μm.

19. The method for manufacturing the illuminating device according to claim 10, wherein the light source comprises a blue light source, and the light-emitting layer comprises a red light-emitting layer and a green light-emitting layer; or
the light source comprises a blue light source, and the light-emitting layer comprises a yellow light-emitting layer.

20. The illuminating device according to claim 2, wherein the light-emitting layer comprises silicate, aluminate or carbonate which are each doped with rare-earth ions, or any combination thereof; or the light-emitting layer comprises silicate, aluminate or carbonate which are each doped with transition metal ions, or any combination thereof.
